(19) United States
(12) Patent Application Publication
(10) Pub. No.: US 2020/0135134 A1
(43) Pub. Date: Apr. 30, 2020

(54) LIQUID CRYSTAL DISPLAY DEVICE AND METHOD OF MANUFACTURING THEREOF

(71) Applicant: Panasonic Liquid Crystal Display Co., Ltd., Himeji-shi (JP)

(72) Inventor: Teruhisa Nakagawa, Hyogo (JP)

(21) Appl. No.: 16/172,322

(22) Filed: Oct. 26, 2018

(51) Int. Cl. G09G 3/36; G02F 1/1335; H01L 27/12

(52) U.S. Cl. CPC G09G 3/3685; G02F 1/133602; H01L 27/1288; G09G 2320/02; G09G 2310/027; G09G 2300/023; G09G 2300/0439

(57) ABSTRACT

A liquid crystal display device comprising a first display panel and a second display panel is provided. The first display panel comprises a plurality of first gate lines and a plurality of first data lines defining a matrix of first pixels in a first display region thereof. The second display panel comprises a plurality of second gate lines and a plurality of second data lines defining a matrix of second pixels in a second display region thereof. The first display panel and the second display panel overlap each other in plan view. The first display panel and the second display panel have equal densities of first pixels and second pixels, respectively, therein. The first display panel displays at a lower definition as compared to the second display panel.

### FIELD OF THE PRESENT DISCLOSURE

The present disclosure relates to liquid crystal display devices, and more particularly to a liquid crystal display device utilizing two display panels.

### BACKGROUND

Liquid crystal displays (LCDs) are commonly used as screens or displays for a wide variety of electronic devices, including such consumer electronics as televisions, computers, and handheld devices (e.g., mobile phones, audio and video players, gaming systems, and so forth). There is a growing consumer demand for delivering better quality LCD devices which have improved contrast ratios in order to provide an enhanced visual experience. A technology, in which two display panels overlap each other and an image is displayed on each display panel based on an input video signal, has been proposed to improve contrast of a liquid crystal display device (for example, see U.S. Pat. No. 8,451,201). Specifically, for example, a color image is displayed on a front-side (observer-side) display panel in two display panels disposed back and forth, and a black-and-white image is displayed on a rear-side (backlight-side) display panel, thereby improving contrast ratio of the LCD device.

However, the inclusion of another display panel adds to already high cost of bill of materials of the LCD device. Therefore, the manufacturers are developing techniques to bring down the overall cost of manufacturing of such LCD device. One such technique has been proposed in US Patent Publication Number 20180081229A1 which discloses a liquid crystal display device comprising: a first display panel and a second display panel, which are overlapping each other; and a backlight disposed on rear surface sides of the first display panel and the second display panel. The backlight irradiates the first display panel and the second display panel with light beams in a plurality of colors while sequentially switching the light beams. Each of the first display panel and the second display panel includes a plurality of pixels. An area of the pixel included in the first display panel is smaller than an area of the pixel included in the second display panel, and correspondingly the cost of such liquid crystal display device can be reduced by reduction of number of drivers required for providing image signals in the second display panel.

It is to be noted that conventional manufacturing method of each of the display panels in the liquid crystal display device involves the photolithography process which requires the use of number of photo-masks. By increasing the number of display panels, the number of photo-masks required may correspondingly be increased. For instance, for LCD with two display panels, conventionally the number of photo-masks required may be doubled. It is to be noted that the photolithography process is a major factor in determination of throughput of a manufacturing process and manufacturing cost.

Furthermore, in the LCDs with two display panels, the additional display panel is typically monochromatic, i.e. without color filter. Such configuration employing a regular display panel with color filter along with a monochromatic display panel helps to provide the improved contrast ratio. However, it has been noted that such additional monochromatic display panel generally requires a longer writing time for corresponding gate lines, in comparison to required writing time for corresponding gate lines of the other display panel with regular color display panel.

The present invention has been made in view of such considerations, and it is an object of the present invention to provide a liquid crystal display device which employ two or more display panels overlapping each other to provide improved contrast ratio while mitigating the issue of long writing time for additional display panel and simultaneously lowering the manufacturing cost thereof.

### SUMMARY

In an aspect, a liquid crystal display device is disclosed. The liquid crystal display device comprises a first display panel comprising a plurality of first gate lines and a plurality of first data lines in a first display region thereof, and a second display panel comprising a plurality of second gate lines and a plurality of second data lines in a second display region thereof. The liquid crystal display device further comprises a first driving circuit for one or more of the plurality of first gate lines and the plurality of first data lines. The first driving circuit comprises one or more first drivers to provide signals to the one or more of the plurality of first gate lines and the plurality of first data lines. In the liquid crystal display device, the first display panel and the second display panel overlap each other in plan view. The plurality of first gate lines and the plurality of first data lines correspond to the plurality of second gate lines and the plurality of second data lines, respectively, in the first display region and the second display region of the first display panel and the second display panel. At least one of two or more adjacent first gate lines from the plurality of first gate lines and two or more adjacent first data lines from the plurality of first data lines are provided with same signals at a same instant of time.

In one or more embodiments, the first driving circuit comprises a first gate driving circuit for the plurality of first gate lines and the one or more first drivers comprise one or more first gate drivers to provide gate signals to the plurality of first gate lines. Two or more adjacent first gate lines from the plurality of first gate lines are provided with the same gate signals at the same instant of time.

In one or more embodiments, the two or more adjacent first gate lines from the plurality of first gate lines are electrically connected to each other by a gate lead connector. The gate lead connector is formed outside the first display region, and connects between the two or more adjacent first gate lines and one gate terminal of the one or more first gate drivers to receive the gate signals for the two or more adjacent first gate lines.

In one or more embodiments, the plurality of first gate lines include a first gate line group of the two or more adjacent first gate lines and a second gate line group of the two or more adjacent first gate lines. The first gate line group and the second gate line group are arranged adjacent to each other. A first gate terminal of the one or more first gate drivers electrically connects to the first gate line group, a second gate terminal of the one or more first gate drivers electrically connects to the second gate line group, and a third gate terminal of the one or more first gate drivers located between the first gate terminal and the second gate terminal is voided.

In one or more embodiments, the first driving circuit comprises a first data driving circuit for the plurality of first data lines and the one or more first drivers comprise one or more first data drivers to provide data signals to the plurality of first data lines. Two or more adjacent first data lines from the plurality of first data lines are provided with the same data signals at the same instant of time.

In one or more embodiments, the two or more adjacent first data lines from the plurality of first data lines are electrically connected to each other by a data lead connector. The data lead connector is formed outside the first display region, and connects between the two or more adjacent first data lines and one data terminal of the one or more first data drivers to receive the data signals for the two or more adjacent first data lines.

In one or more embodiments, the plurality of first data lines include a first data line group of the two or more adjacent first data lines and a second data line group of the two or more adjacent first data lines. The first data line group and the second data line group are arranged adjacent to each other. A first data terminal of the one or more first data drivers electrically connects to the first data line group, a second data terminal of the one or more first data drivers electrically connects to the second data line group, and a third data terminal of the one or more first data drivers located between the first data terminal and the second data terminal is voided.

In one or more embodiments, the liquid crystal display device further comprises a second driving circuit for one or more of the plurality of second gate lines and the plurality of second data lines. The second driving circuit comprises one or more second drivers to provide signals to the one or more of the plurality of second gate lines and the plurality of second data lines. A number of first drivers are less than a number of second drivers.

In one or more embodiments, the liquid crystal display device further comprises a second driving circuit for one or more of the plurality of second gate lines and the plurality of second data lines. The second driving circuit comprises one or more second drivers to provide signals to the one or more of the plurality of second gate lines and the plurality of second data lines. A number of terminals in the one or more first drivers are less than a number of terminals in the one or more second drivers.

In another aspect, a liquid crystal display device is disclosed. The liquid crystal display device comprises a first display panel comprising a plurality of first gate lines and a plurality of first data lines in a first display region thereof. Two adjacent first gate lines from the plurality of first gate lines and two adjacent first data lines from the plurality of first data lines define a first pixel in the first display region. The liquid crystal display device further comprises a second display panel comprising a plurality of second gate lines and a plurality of second data lines in a second display region thereof. Two adjacent second gate lines from the plurality of second gate lines and two adjacent second data lines from the plurality of second data lines define a second pixel in the second display region. The first display panel and the second display panel overlap each other in plan view. The first display panel and the second display panel have equal densities of first pixels and second pixels, respectively, therein. The first display panel displays at a lower definition as compared to the second display panel.

In one or more embodiments, the first driving circuit comprises a first gate driving circuit for the plurality of first gate lines and the one or more first drivers comprise one or more first gate drivers to provide gate signals to the plurality of first gate lines. Two or more adjacent first gate lines from the plurality of first gate lines are provided with the same gate signals at the same instant of time.

In one or more embodiments, the two or more adjacent first gate lines from the plurality of first gate lines are electrically connected to each other by a gate lead connector. The gate lead connector is formed outside the first display region, and connects between the two or more adjacent first gate lines and one gate terminal of the one or more first gate drivers to receive the gate signals for the two or more adjacent first gate lines.

In one or more embodiments, the plurality of first gate lines include a first gate line group of the two or more adjacent first gate lines and a second gate line group of the two or more adjacent first gate lines. The first gate line group and the second gate line group are arranged adjacent to each other. A first gate terminal of the one or more first gate drivers electrically connects to the first gate line group, a second gate terminal of the one or more first gate drivers electrically connects to the second gate line group, and a third gate terminal of the one or more first gate drivers located between the first gate terminal and the second gate terminal is voided.

In one or more embodiments, the first driving circuit comprises a first data driving circuit for the plurality of first data lines and the one or more first drivers comprise one or more first data drivers to provide data signals to the plurality of first data lines. Two or more adjacent first data lines from the plurality of first data lines are provided with data signals of same gray scale at the same instant of time.

In one or more embodiments, the two or more adjacent first data lines from the plurality of first data lines are electrically connected to each other by a data lead connector. The data lead connector is formed outside the first display region, and connects between the two or more adjacent first data lines and one data terminal of the one or more first data drivers to receive the data signals for the two or more adjacent first data lines.

In one or more embodiments, the plurality of first data lines include a first data line group of the two or more adjacent first data lines and a second data line group of the two or more adjacent first data lines. The first data line group and the second data line group are arranged adjacent to each other. A first data terminal of the one or more first data drivers electrically connects to the first data line group, a second data terminal of the one or more first data drivers electrically connects to the second data line group, and a third data terminal of the one or more first data drivers located between the first data terminal and the second data terminal is voided.

In yet another aspect, a method of manufacturing a liquid crystal display device is disclosed. The liquid crystal display device comprises a first display panel including a plurality of first gate lines, a plurality of first data lines, and a plurality of pixel electrodes in a first display region thereof, and a second display panel comprising a plurality of second gate lines and a plurality of second data lines, and a plurality of second pixel electrodes in a second display region thereof. The first display panel and the second display panel overlap each other in plan view. The method comprises a first series of photolithography steps for manufacturing the first display panel and a second series of photolithography steps for manufacturing the second display panel. The first series of photolithography steps comprises a first gate line step of forming the plurality of first gate lines by a first photo-mask, a first data line step of forming the plurality of first data lines by a second photo-mask, and a first pixel electrode step of forming the plurality of first pixel electrodes by a third photo-mask. The second series of photolithography steps comprises a second gate line step of forming the plurality of second gate lines by a fourth photo-mask, a second data line step of forming the plurality of second data lines by a fifth photo-mask, and a second pixel electrode step of forming the plurality of second pixel electrodes by a sixth photo-mask. The third photo-mask and the sixth photo-mask have a same shape, and at least one of the first photo-mask and the second photo-mask has a different shape from the fourth photo-mask and the fifth photo-mask, respectively.

In one or more embodiments, common shape of photo-mask is used in both each step from the first series of photolithography steps and each corresponding step from the second series of photolithography steps, other than at least one of both of the first gate line step and the second gate line step, and both of the first data line step and the second data line step.

In one or more embodiments, the first photo-mask has a different shape from the fourth photo-mask, and the second photo-mask has a different shape from the fifth photo-mask.

In one or more embodiments, two or more adjacent first gate lines from the plurality of first gate lines are electrically connected to each other by a gate lead connector, two or more adjacent first data lines from the plurality of first data lines are electrically connected to each other by a data lead connector, or the two or more adjacent first gate lines and the two or more adjacent first data lines are electrically connected to each other by the gate lead connector and the data lead connector, respectively.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

For a more complete understanding of example embodiments of the present disclosure, reference is now made to the following descriptions taken in connection with the accompanying drawings in which:

FIG. 1 is a perspective view illustrating a schematic configuration of a liquid crystal display device, in accordance with one or more exemplary embodiments of the present disclosure;

FIG. 2 is a schematic view illustrating the configuration of the liquid crystal display device of FIG. 1, in accordance with one or more exemplary embodiments of the present disclosure;

FIG. 3 is a plan view illustrating a schematic configuration of a second display panel, in accordance with one or more exemplary embodiments of the present disclosure;

FIG. 4 is a plan view illustrating a schematic configuration of a first display panel, in accordance with a first exemplary embodiment of the present disclosure;

FIG. 5 is a plan view illustrating a schematic configuration of the first display panel, in accordance with a second exemplary embodiment of the present disclosure;

FIG. 6 is a plan view illustrating a schematic configuration of the first display panel, in accordance with a third exemplary embodiment of the present disclosure;

FIG. 7 is a plan view illustrating a schematic configuration of the first display panel, in accordance with a fourth exemplary embodiment of the present disclosure;

FIG. 8 is a plan view illustrating a schematic configuration of the first display panel, in accordance with a fifth exemplary embodiment of the present disclosure;

FIG. 9 is a plan view illustrating a schematic configuration of the first display panel, in accordance with a sixth exemplary embodiment of the present disclosure;

FIG. 10 is a plan view illustrating a schematic configuration of the first display panel, in accordance with a seventh exemplary embodiment of the present disclosure;

FIG. 11A is a plan view illustrating a first photo-mask, in accordance with one or more exemplary embodiments of the present disclosure;

FIG. 11B is a plan view illustrating a portion of a layer of the first display panel as formed by a first gate line step using the first photo-mask, in accordance with one or more exemplary embodiments of the present disclosure;

FIG. 12A is a plan view illustrating a second photo-mask, in accordance with one or more exemplary embodiments of the present disclosure;

FIG. 12B is a plan view illustrating a portion of a layer of the first display panel as formed by a first data line step using the second photo-mask, in accordance with one or more exemplary embodiments of the present disclosure;

FIG. 13A is a plan view illustrating a third photo-mask, in accordance with one or more exemplary embodiments of the present disclosure;

FIG. 13B is a plan view illustrating a portion of a layer of the first display panel as formed by a first pixel electrode step using the third photo-mask, in accordance with one or more exemplary embodiments of the present disclosure;

FIG. 14A is a plan view illustrating a fourth photo-mask, in accordance with one or more exemplary embodiments of the present disclosure;

FIG. 14B is a plan view illustrating a portion of a layer of the second display panel as formed by a second gate line step using the fourth photo-mask, in accordance with one or more exemplary embodiments of the present disclosure;

FIG. 15A is a plan view illustrating a fifth photo-mask, in accordance with one or more exemplary embodiments of the present disclosure;

FIG. 15B is a plan view illustrating a portion of a layer of the second display panel as formed by a second data line step using the fifth photo-mask, in accordance with one or more exemplary embodiments of the present disclosure;

FIG. 16A is a plan view illustrating a sixth photo-mask, in accordance with one or more exemplary embodiments of the present disclosure; and

FIG. 16B is a plan view illustrating a portion of a layer of the second display panel as formed by a second pixel electrode step using the sixth photo-mask, in accordance with one or more exemplary embodiments of the present disclosure.

### DETAILED DESCRIPTION

In the following description, for purposes of explanation, numerous specific details are set forth in order to provide a thorough understanding of the present disclosure. It will be apparent, however, to one skilled in the art that the present disclosure is not limited to these specific details.

Reference in this specification to “one embodiment” or “an embodiment” means that a particular feature, structure, or characteristic described in connection with the embodiment is included in at least one embodiment of the present disclosure. The appearance of the phrase “in one embodiment” in various places in the specification are not necessarily all referring to the same embodiment, nor are separate or alternative embodiments mutually exclusive of other embodiments. Further, the terms “a” and “an” herein do not denote a limitation of quantity, but rather denote the presence of at least one of the referenced item. Moreover, various features are described which may be exhibited by some embodiments and not by others. Similarly, various requirements are described which may be requirements for some embodiments but not for other embodiments.

A liquid crystal display device of each exemplary embodiment described below includes a plurality of display panels that display images, a plurality of driving circuits (a plurality of source drivers and a plurality of gate drivers) that drive the display panels, a plurality of timing controllers that control the driving circuits, an image processor that performs image processing on an input video signal input from an outside and outputs image data to each of the timing controllers, and a backlight that irradiates the plurality of display panels with light from a rear surface side. There is no limitation to the number of display panels, but it is only necessary to provide at least two display panels. The plurality of display panels are disposed while overlapping each other in a front-rear direction, and an image is displayed on each of the display panels. A liquid crystal display device including two display panels has been described in the present disclosure by way of example.

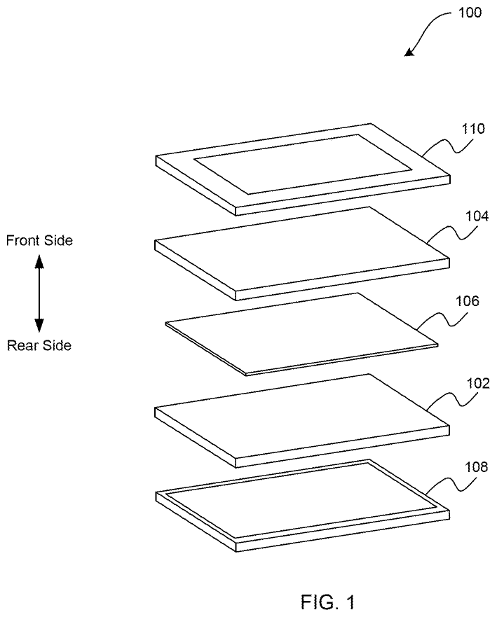

FIG. 1 is a perspective view illustrating a schematic configuration of a liquid crystal display device (generally referenced by the numeral 100), according to an exemplary embodiment of the present disclosure. As illustrated in FIG. 1, the liquid crystal display device 100 includes a first display panel 102 which is disposed, generally, at a rear side (farther away from the observer), and a second display panel 104 which is disposed, generally, at a front side (closer to an observer than the first display panel 102), when the liquid crystal display device 100 is being implemented by the observer for viewing purposes. In the present examples, the first display panel 102 and the second display panel 104 overlap each other in plan view, as may also be contemplated from FIG. 1. In one or more examples, an adhesive layer 106 may be employed by which the first display panel 102 and the second display panel 104 adhere to each other. Further, a backlight 108 may be disposed on the rear side with respect to the first display panel 102, and further a front chassis 110 may be provided that covers the first display panel 102 and the second display panel 104 from the front side.

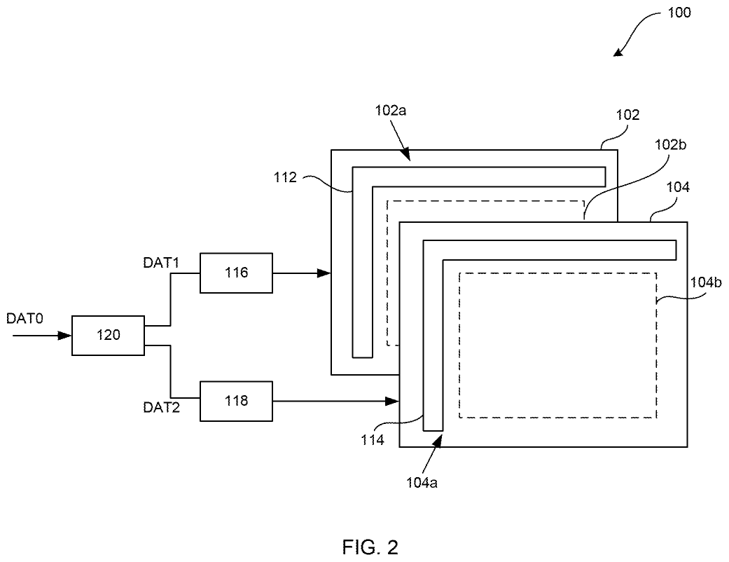

FIG. 2 is a view illustrating the schematic configuration of the liquid crystal display device 100 of the present exemplary embodiment. As illustrated in FIG. 2, the first display panel 102 includes a first driving circuit 112 and the second display panel 104 includes a second driving circuit 114. It may be seen that the first driving circuit 112 is disposed in a first non-display region 102a, bordering a first display region 102b, in the first display panel 102. Similarly, the second driving circuit 114 is disposed in a second non-display region 104a, bordering a second display region 104b, in the second display panel 104. In addition, the liquid crystal display device 100 includes a first timing controller 116 that controls the first driving circuit 112 and a second timing controller 118 that controls the second driving circuit 114, and an image processor 120 that outputs image data to the first timing controller 116 and the second timing controller 118. The image processor 120 receives input video signals data DAT0 transmitted from an external system (not illustrated), performs known image processing on the input video signal data DAT0, outputs first image signal data DAT1 to the first timing controller 116 and outputs second image signal data DAT2 to the second timing controller 118. The image processor 120 may also output a control signal (not shown in FIG. 2) such as a synchronizing signal to the first timing controller 116 and the second timing controller 118. In the liquid crystal display device 100, the first display panel 102 displays an image in the first display region 102b thereof according to the first image signal data DAT1, and the second display panel 104 displays an image in the second display region 104b thereof according to the second image signal data DAT2.

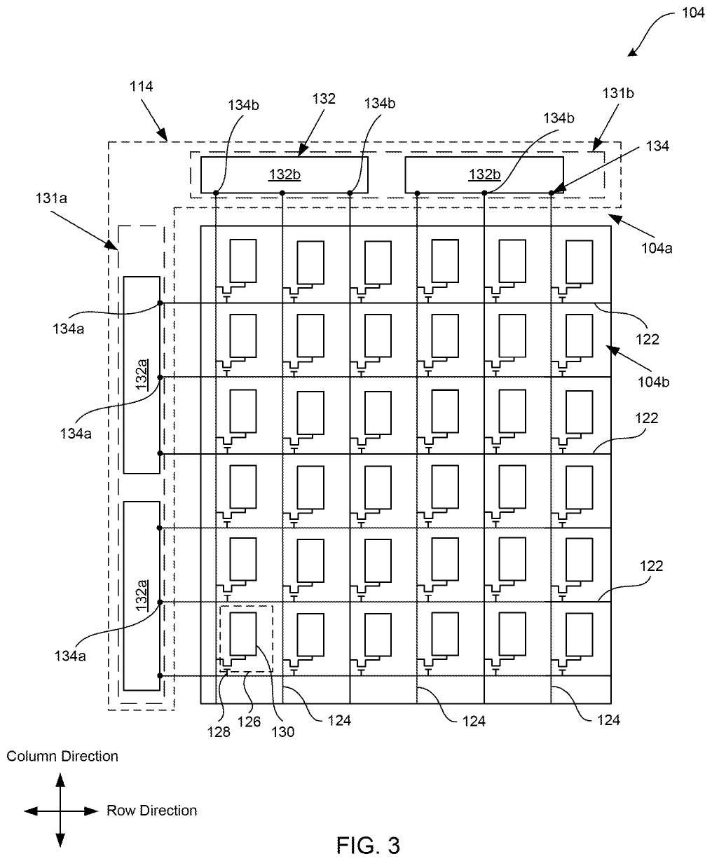

FIG. 3 is a plan view illustrating a schematic configuration of the second display panel 104, according to one or more exemplary embodiments. As illustrated, the second display panel 104 includes a plurality of second gate lines 122 (generally extending in a row direction) and a plurality of second data lines 124 (generally extending in a column direction), which are arranged in the second display region 104b. Generally, the plurality of second gate lines 122 are disposed at equal intervals in the column direction, and the plurality of second data lines 124 are disposed at equal intervals in the row direction. In the plan view of the second display panel 104, a region surrounded by two second gate lines 122 adjacent to each other and two second data lines 124 adjacent to each other is defined as one second pixel 126, and a plurality of second pixels 126 are disposed in a matrix form (the row direction and the column direction) in the second display region 104b. A second thin-film transistor (TFT) 128 is provided for each of the plurality of second pixels 126 for operation thereof. Further, as illustrated, a second pixel electrode 130 is formed for each of the plurality of second pixels 126, in the second display panel 104.

Further, as illustrated, the second driving circuit 114 is connected to one or more of the plurality of second gate lines 122 and the plurality of second data lines 124. In particular, the second driving circuit 114 includes a second gate driving circuit 131a having one or more second gate drivers 132a to provide gate signals to the one or more of the plurality of second gate lines 122 and a second data driving circuit 131b having one or more second data drivers 132b to provide data signals to the one or more of the plurality of second data lines 124. Hereinafter, the one or more second gate drivers 132a and the one or more second data drivers 132b are, sometimes, collectively referred to as one or more second drivers 132 which may be understood to provide signals to the one or more of the plurality of second gate lines 122 and the plurality of second data lines 124, in the second driving circuit 114. Specifically, each of the one or more second gate drivers 132a includes one or more gate terminals 134a therein, and each of the one or more second data drivers 132b includes one or more data terminals 134b therein. Hereinafter, the gate terminals 134a and the data terminals 134b are, sometimes, collectively referred to as second terminals 134. Further, each of the plurality of second gate lines 122 is electrically connected to one of the gate terminals 134a and each of the plurality of second data lines 124 is electrically connected to one of the data terminals 134b in the one or more second gate drivers 132a and the one or more second data drivers 132b, respectively, corresponding thereto. It may be seen, from FIG. 3, that in the second display panel 104, each of the plurality of second gate lines 122 and the plurality of second data lines 124 is individually electrically connected to one of the second terminals 134 in the one of the second drivers 132.

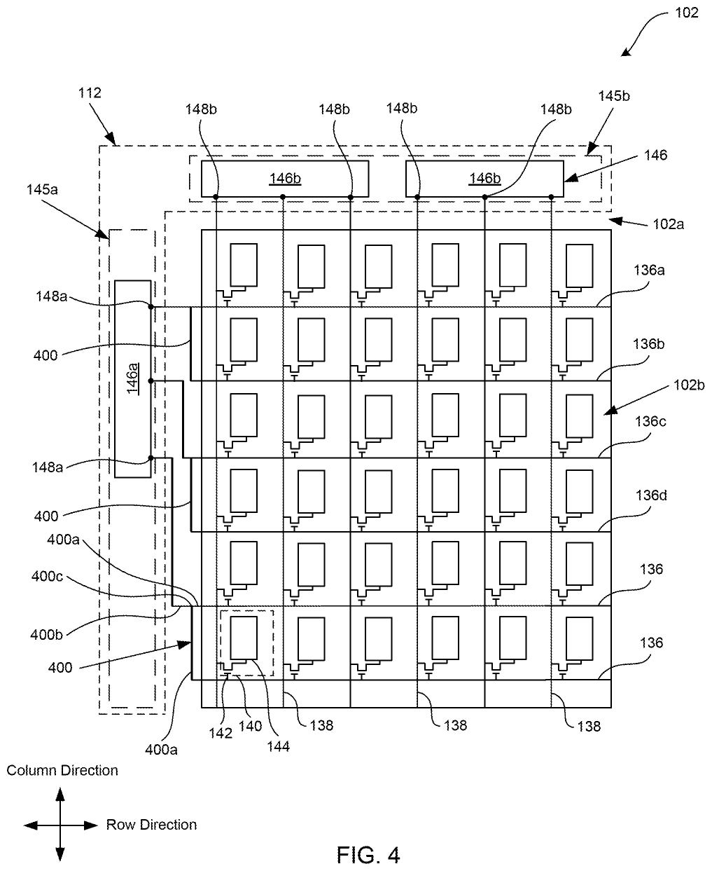

FIGS. 4-10 are plan views illustrating schematic configurations of the first display panel 102, according to different exemplary embodiments of the present disclosure. As illustrated, the first display panel 102 includes a plurality of first gate lines 136 (generally extending in a row direction) and a plurality of first data lines 138 (generally extending in a column direction), which are arranged in the first display region 102b. Generally, the plurality of first gate lines 136 are disposed at equal intervals in the column direction, and the plurality of first data lines 138 are disposed at equal intervals in the row direction. In the plan view of the first display panel 102, a region surrounded by two first gate lines 136 adjacent to each other and two first data lines 138 adjacent to each other is defined as one first pixel 140, and a plurality of first pixels 140 are disposed in a matrix form (the row direction and the column direction) in the first display region 102b. A first thin-film transistor (TFT) 142 is provided for each of the plurality of first pixels 140 for operation thereof. Further, as illustrated, a first pixel electrode 144 is formed for each of the plurality of first pixels 140, in the first display panel 102.

Further, as illustrated, the first driving circuit 112 is connected to one or more of the plurality of first gate lines 136 and the plurality of first data lines 138. In particular, the first driving circuit 112 includes a first gate driving circuit 145a having one or more first gate drivers 146a to provide gate signals to the one or more of the plurality of first gate lines 136 and a first data driving circuit 145b having one or more first data drivers 146b to provide data signals to the one or more of the plurality of first data lines 138. Hereinafter, the one or more first gate drivers 146a and the one or more first data drivers 146b are, sometimes, collectively referred to as one or more first drivers 146 which may be understood to provide signals to the one or more of the plurality of first gate lines 136 and the plurality of first data lines 138, in the first driving circuit 112. Specifically, each of the one or more first gate drivers 146a includes one or more gate terminals 148a therein, and each of the one or more first data drivers 146b includes one or more data terminals 148b therein. Hereinafter, the gate terminals 148a and the data terminals 148b are, sometimes, collectively referred to as first terminals 148. Further, each of the plurality of first gate lines 136 is electrically connected to one of the gate terminals 148a and each of the plurality of first data lines 138 is electrically connected to one of the data terminals 148b in the one or more first gate drivers 146a and the one or more second data drivers 146b, respectively, corresponding thereto.

In the exemplary embodiments of the present disclosure, the plurality of first gate lines 136 and the plurality of first data lines 138 correspond to the plurality of second gate lines 122 and the plurality of second data lines 124, respectively, in the first display region 102b and the second display region 104b of the first display panel 102 and the second display panel 104, respectively, when the first display panel 102 and the second display panel 104 overlap each other in plan view of the liquid crystal display device 100. In other words, the first display panel 102 and the second display panel 104 have equal densities of the first pixels 140 and the second pixels 126, respectively, therein. Further, in the exemplary embodiments of the first display panel 102, as illustrated in FIGS. 4-10, at least one of two or more adjacent first gate lines from the plurality of first gate lines 136 and two or more adjacent first data lines from the plurality of first data lines 138 are provided with same signals by the corresponding first drivers 146 at a same instant of time, in the first driving circuit 112. In other words, the first display panel 102 displays at a lower definition as compared to the second display panel 104, in the liquid crystal display device 100 of the present disclosure.

It may be appreciated that since the final image is determined by the second display panel 104 in the liquid crystal display device 100, therefore the first display panel 102 can have lower definition as compared to the second display panel 104. Furthermore, since the first display panel 102 is accepted to operate at lower definition; therefore, the first display panel 102 can employ longer writing time for its operations (as discussed below) in the present liquid crystal display device 100.

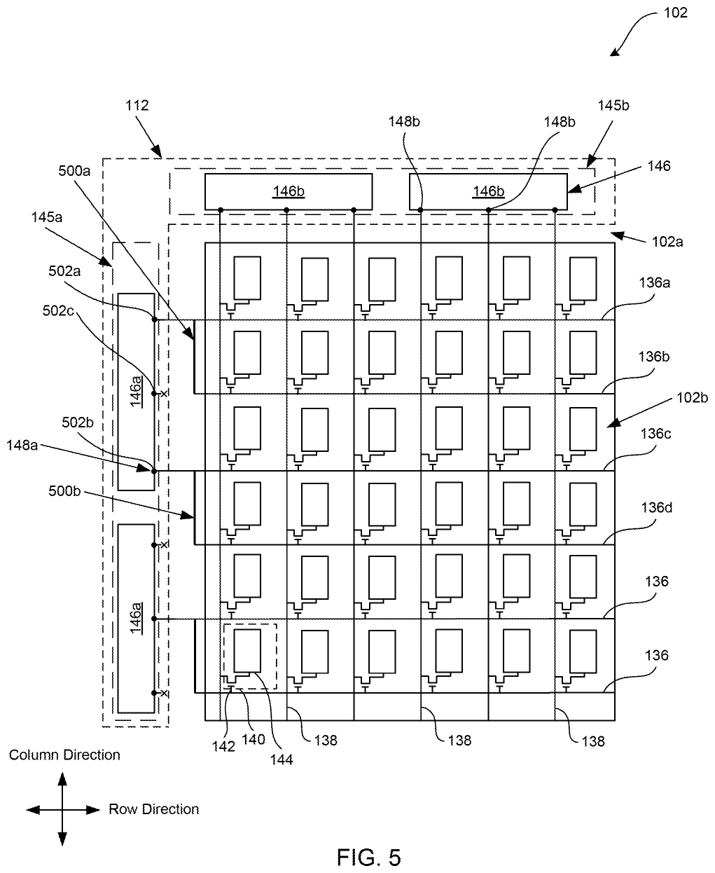

FIG. 4 is a plan view illustrating schematic configuration of the first display panel 102, according to a first exemplary embodiment of the present disclosure. Further, FIG. 5 is a plan view illustrating schematic configuration of the first display panel 102, according to a second exemplary embodiment of the present disclosure. In the said first and second exemplary embodiments of the first display panel 102, as illustrated in FIGS. 4-5, two or more adjacent first gate lines, such as gate lines 136a and 136b, from the plurality of first gate lines 136 are provided with the same gate signals at the same instant of time.

Referring to FIG. 4, in particular, the two or more adjacent first gate lines, such as the gate lines 136a and 136b, from the plurality of first gate lines 136 are electrically connected to each other by a gate lead connector 400. As illustrated, the gate lead connector 400 is formed in the first non-display region 102a, outside the first display region 102b, and connects between the two or more adjacent first gate lines 136a and 136b and one of the gate terminals 148a of the one or more first gate drivers 146a to receive the gate signals for the two or more adjacent first gate lines 136a and 136b. For this purpose, the gate lead connector 400 may include two or more first connectors 400a and a second connector 400b, and the two or more first connectors 400a and the second connector 400b are connected to each other at a connecting point 400c. Each of the two or more first connectors 400a may be electrically connected to one of the two or more adjacent first gate lines 136a and 136b, and the second connector 400b may be electrically connected to one of the gate terminals 148a of the one or more first gate drivers 146a to receive the gate signals for the two or more adjacent first gate lines 136a and 136b to be transmitted via the two or more first connectors 400a.

In the present first exemplary embodiment, it may be seen that two or more first gate lines 136 may receive gate signals from only one of the gate terminals 148a of the one or more first gate drivers 146a. Since the number of first gate lines 136 corresponds to the number of second gate lines 122, this results in reduced requirement, and thus lesser number, of the gate terminals 148a in the one or more first gate drivers 146a of the first driving circuit 112 as compared to number of the gate terminals 134a in the one or more second gate drivers 132a of the second driving circuit 114. It may be appreciated that, alternatively, the first driving circuit 112 may be provided with lesser number of the first gate drivers 146a as compared to the number of second gate drivers 132a in the second driving circuit 114. Further, in such case, the first gate drivers 146a may be configured such that an interval between sending of gate signals to the two adjacent first gate lines 136 (such as the first gate lines 136a and 136b) and the next two adjacent first gate lines 136 (such as first gate lines 136c and 136d) is longer than an interval between sending of gate signals to the two adjacent second gate lines 122, thus providing longer writing time for the first gate lines 136 in the first display panel 102 as compared to available writing time for the second gate lines 122 in the second display panel 104.

Referring to FIG. 5, in particular, two or more of adjacent first gate lines 136 of the plurality of first gate lines 136 are grouped together. In particular, the first display panel 102 includes a first gate line group 500a of the two or more adjacent first gate lines, such as the first gate lines 136a and 136b; and a second gate line group 500b of the two or more adjacent first gate lines, such as the first gate lines 136c and 136d. The first gate line group 500a and the second gate line group 500b are arranged adjacent to each other. Further, the gate terminals 148a in the one or more first gate drivers 146a (for example, in at least one of the first gate drivers 146a, or two or more of the adjacent first gate drivers 146a) include a first gate terminal 502a, a second gate terminal 502b and a third gate terminal 502c, such that the third gate terminal 502c is located between the first gate terminal 502a and the second gate terminal 502b. The first gate terminal 502a electrically connects to the first gate line group 500a, the second gate terminal 502b electrically connects to the second gate line group 500b and the third gate terminal 502c is voided. Herein, the term “voided” means that the corresponding terminal is present but is cut-off so that terminal could not send signals to the corresponding line; however, it is to be noted that the terminal is capable of sending the corresponding signals if required thereby, by connecting the terminal with the corresponding line of the display panel.

In the present second exemplary embodiment, since every alternate gate terminal of the gate terminals 148a is voided, it may be contemplated by a person skilled in the art that this increases interval between sending of gate signals to the two adjacent first gate lines 136, thus providing longer writing time for the plurality of first gate lines 136 in the first display panel 102 as compared to available writing time for the plurality of second gate lines 122 in the second display panel 104. Further, it may be appreciated that such configuration of the first display panel 102 utilizes the same number and placement of the gate drivers 146 as may be implemented in the second display panel 104, thereby allowing to implement the same drivers without additional cost for developing a new driver for new panel array.

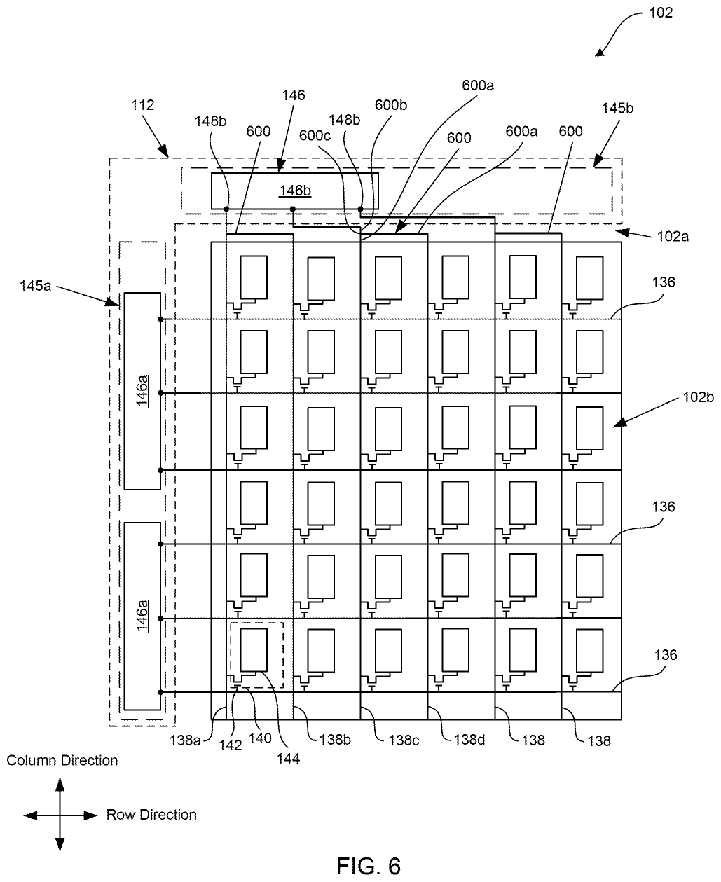

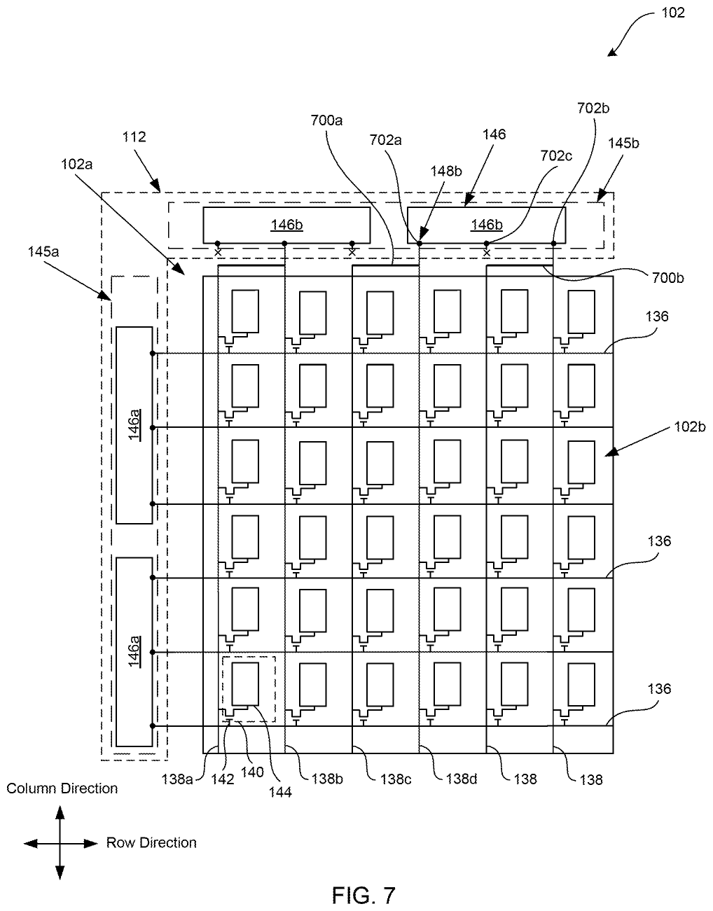

FIG. 6 is a plan view illustrating schematic configuration of the first display panel 102, according to a third exemplary embodiment of the present disclosure. Further, FIG. 7 is a plan view illustrating schematic configuration of the first display panel 102, according to a fourth exemplary embodiment of the present disclosure. In the said third and fourth exemplary embodiments of the first display panel 102, as illustrated in FIGS. 6-7, two or more adjacent first data lines, such as data lines 138a and 138b, from the plurality of first data lines 138 are provided with the same data signals and/or data signals of the same gray scale at the same instant of time.

Referring to FIG. 6, in particular, the two or more adjacent first data lines, such as the data lines 138a and 138b, from the plurality of first data lines 138 are electrically connected to each other by a data lead connector 600. As illustrated, the data lead connector 600 is formed in the first non-display region 102a, outside the first display region 102b, and connects between the two or more adjacent first data lines 138a and 138b and one of the data terminals 148b of the one or more first data drivers 146b to receive the data signals for the two or more adjacent first data lines 138a and 138b. For this purpose, the data lead connector 600 may include two or more first connectors 600a, and a second connector 600b, and the two or more first connectors 600a and the second connector 600b are connected to each other at a connecting point 600c. Each of the two or more first connectors 600a may be electrically connected to one of the two or more adjacent first data lines 138a and 138b, and the second connector 600b may be electrically connected to one of the data terminals 148b of the one or more first data drivers 146b to receive the data signals for the two or more adjacent first data lines 138a and 138b to be transmitted via the two or more first connectors 600a.

In the present third exemplary embodiment, it may be seen that two or more first data lines 138 may receive data signals from only one of the data terminals 148b of the one or more first data drivers 146b. Since the number of first data lines 138 corresponds to the number of second data lines 124, this results in reduced requirement, and thus lesser number, of the data terminals 148b in the one or more first data drivers 146b of the first driving circuit 112 as compared to number of the data terminals 134b in the one or more second data drivers 132b of the second driving circuit 114. It may be appreciated that, alternatively, the first driving circuit 112 may be provided with lesser number of the first data drivers 146b as compared to the number of second data drivers 132b in the second driving circuit 114.

Referring to FIG. 7, in particular, two or more adjacent first data lines 138 of the plurality of first data lines 138 are grouped together. In particular, the first display panel 102 includes a first data line group 700a of the two or more adjacent first data lines, such as the first data lines 138a and 138b; and a second data line group 700b of the two or more adjacent first data lines, such as the first data lines 138c and 138d. The first data line group 700a and the second data line group 700b are arranged adjacent to each other. Further, the data terminals 148b in the one or more first data drivers 146b (for example, in at least one of the first data drivers 146b, or two or more of the adjacent first data drivers 146b) include a first data terminal 702a, a second data terminal 702b and a third data terminal 702c, such that the third data terminal 702c is located between the first data terminal 702a and the second data terminal 702b. The first data terminal 702a electrically connects to the first data line group 700a, the second data terminal 702b electrically connects to the second data line group 700b and the third data terminal 702c is voided.

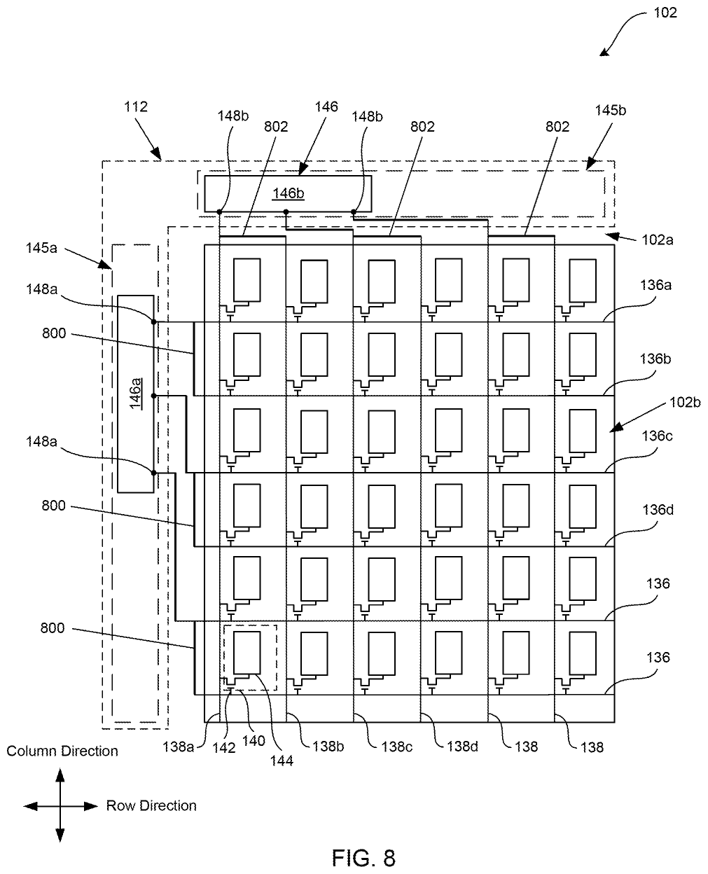

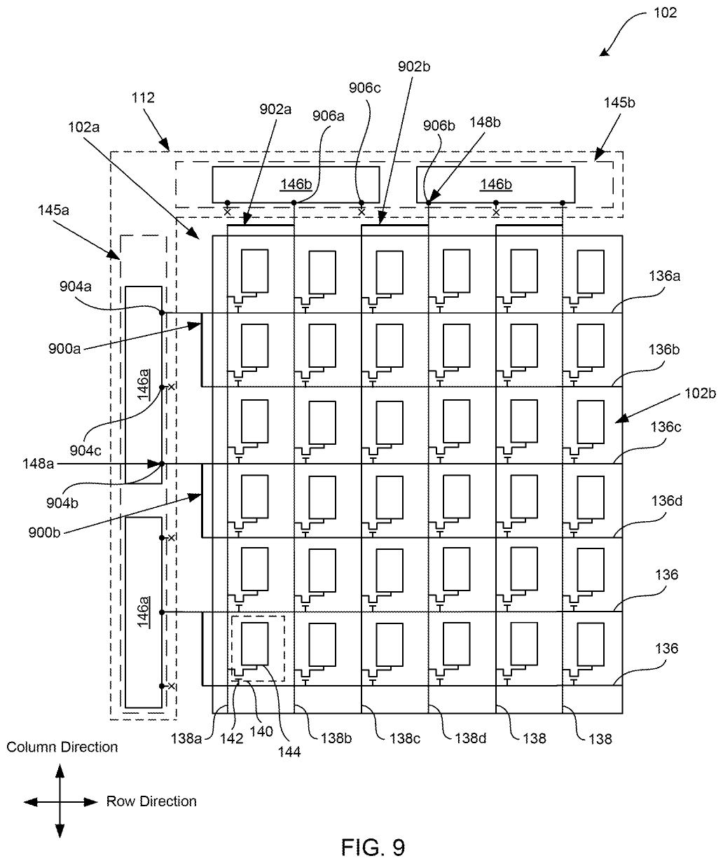

FIG. 8 is a plan view illustrating schematic configuration of the first display panel 102, according to a fifth exemplary embodiment of the present disclosure. Further, FIG. 9 is a plan view illustrating schematic configuration of the first display panel 102, according to a sixth exemplary embodiment of the present disclosure. In the said fifth and sixth exemplary embodiments of the first display panel 102, as illustrated in FIGS. 8-9, two or more adjacent first gate lines (such as gate lines 136a and 136b) and two or more adjacent first data lines (such as data lines 138a and 138b) from the plurality of first gate lines 136 and the plurality of first data lines 138, respectively, are provided with the same gate signals and the same data signals at the corresponding same instant of time.

Referring to FIG. 8, in particular, the two or more adjacent first gate lines, such as the gate lines 136a and 136b, from the plurality of first gate lines 136 are electrically connected to each other by a gate lead connector 800; and the two or more adjacent first data lines, such as the data lines 138a and 138b, from the plurality of first data lines 138 are electrically connected to each other by a data lead connector 802. As illustrated, the gate lead connector 800 is formed in the first non-display region 102a, outside the first display region 102b, and connects between the two or more adjacent first gate lines 136a and 136b and one of the gate terminals 148a of the one or more first gate drivers 146a to receive the gate signals for the two or more adjacent first gate lines 136a and 136b. Further, as illustrated, the data lead connector 802 is formed in the first non-display region 102a, outside the first display region 102b, and connects between the two or more adjacent first data lines 138a and 138b and one of the data terminals 148b of the one or more first data drivers 146b to receive the data signals for the two or more adjacent first data lines 138a and 138b.

In the present fifth exemplary embodiment, it may be seen that two or more first gate lines 136 may receive gate signals from only one of the gate terminals 148a of the one or more first gate drivers 146a and further two or more first data lines 138 may receive data signals from only one of the data terminals 148b of the one or more first data drivers 146b. Since the number of first gate lines 136 corresponds to the number of second gate lines 122, this results in reduced requirement, and thus lesser number, of the first terminals 148 in the one or more first drivers 146 of the first driving circuit 112 as compared to number of the second terminals 134 in the one or more second drivers 132 of the second driving circuit 114. It may be appreciated that, alternatively, the first driving circuit 112 may be provided with lesser number of the first drivers 146 as compared to the number of second drivers 132 in the second driving circuit 114. Further, in such case, it will be appreciated that longer writing time is provided for the first gate lines 136 in the first display panel 102 as compared to available writing time for the second gate lines 122 in the second display panel 104.

Referring to FIG. 9, in particular, two or more of adjacent first gate lines 136 of the plurality of first gate lines 136 are grouped together and further two or more adjacent first data lines 138 of the plurality of first data lines 138 are grouped together. In particular, the first display panel 102 includes a first gate line group 900a of the two or more adjacent first gate lines (such as the first gate lines 136a and 136b), and a second gate line group 900b of the two or more adjacent first gate lines (such as the first gate lines 136c and 136d); a first data line group 902a of the two or more adjacent first data lines, such as the first data lines 138a and 138b; and a second data line group 902b of the two or more adjacent first data lines, such as the first data lines 138c and 138d. The first gate line group 900a and the second gate line group 900b are arranged adjacent to each other; and further the first data line group 902a and the second data line group 902b are arranged adjacent to each other. Further, the gate terminals 148a in the one or more first gate drivers 146a (for example, in at least one of the first gate drivers 146a, or two or more of the adjacent first gate drivers 146a) include a first gate terminal 904a, a second gate terminal 904b and a third gate terminal 904c, such that the third gate terminal 904c is located between the first gate terminal 904a and the second gate terminal 904b. The first gate terminal 904a electrically connects to the first gate line group 900a, the second gate terminal 904b electrically connects to the second gate line group 900b and the third gate terminal 904c is voided. Similarly, the data terminals 148b in the one or more first data drivers 146b (for example, in at least one of the first data drivers 146b, or two or more of the adjacent first data drivers 146b) include a first data terminal 906a, a second data terminal 906b and a third data terminal 906c, such that the third data terminal 906c is located between the first data terminal 906a and the second data terminal 906b. The first data terminal 906a electrically connects to the first data line group 902a, the second data terminal 906b electrically connects to the second data line group 902b and the third data terminal 906c is voided.

In the present sixth exemplary embodiment, since every alternate gate terminal of the gate terminals 148a is voided and every alternate data terminal of the data terminals 148b is voided, it may be contemplated by a person skilled in the art that this increases interval between sending of gate signals to the corresponding two adjacent first gate lines 136, thus providing longer writing time for the plurality of first gate lines 136 in the first display panel 102 as compared to available writing time for the corresponding plurality of second gate lines 122 in the second display panel 104.

In at least some of the exemplary embodiments of FIGS. 4-9, a number of first drivers 146 are less than a number of second drivers 132. The reduced number of first drivers 146 may result in reduction of the overall cost of manufacturing of the first display panel 102. Additionally, or alternatively, a number of terminals 148 in the one or more first drivers 146 are less than a number of terminals 134 in the one or more second drivers 132. The reduced number of terminals 148 in the first drivers 146 may allow to use available cost-efficient drivers as the first drivers 146, which may result in reduction of the overall cost of manufacturing of the first display panel 102.

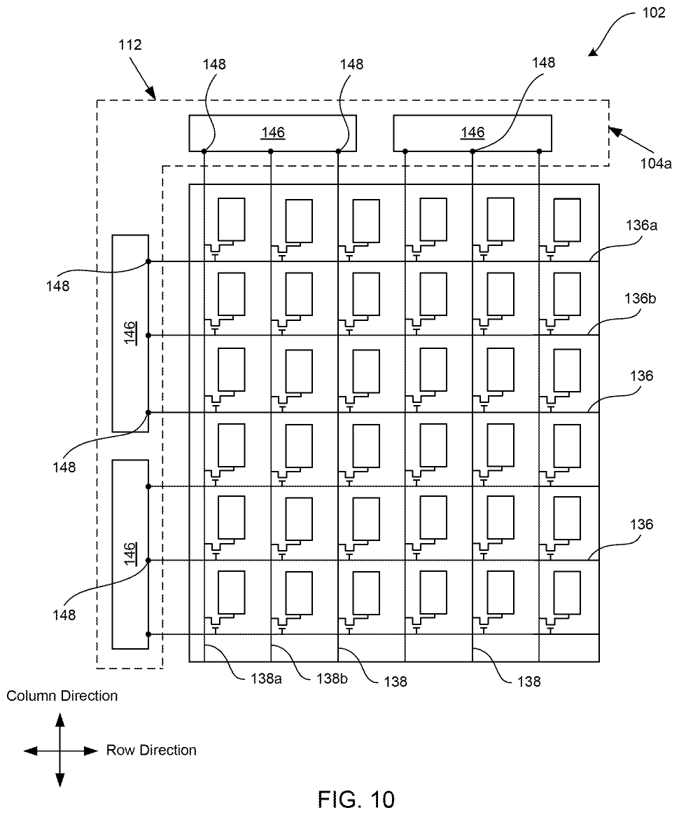

FIG. 10 is a plan view illustrating schematic configuration of the first display panel 102, according to a seventh exemplary embodiment of the present disclosure. In the present seventh exemplary embodiment, as illustrated, the first display panel 104 includes each of the plurality of first gate lines 136 and the plurality of first data lines 138 electrically connected to one individual first terminal 148 in the corresponding first driver 146, similar to the second panel 104. The first drivers 146 are configured such that one or more of two adjacent first gate lines 136 (such as, the first gate lines 136a and 136b) and two adjacent first data lines 138 (such as, the first data lines 138a and 138b) are provided with corresponding gate signals and data signals at a same instant of time. This is in contrast to the second display 104 in which two adjacent second gate lines 122 and two adjacent second data lines 124 are provided with corresponding gate signals and data signals with an interval therebetween. This, in turn, allows that each of the plurality of first gate lines 136 and the plurality of first data lines 138 would have about twice the writing time therefor in the first display panel 102 as compared to available writing time for each of the plurality of second gate lines 122 in the second display panel 104. Furthermore, reduction in the writing time may allow to employ low-frequency available drivers as the first drivers 146, which may be cost-efficient and result in reduction of the overall cost of manufacturing of the first display panel 102.

The present disclosure further provides a method of manufacturing the liquid crystal display device 100 including the two display panels, namely the first display panel 102 and the second display panel 104. The two display panels 102 and 104 are formed by photolithography techniques which employs multiple photo-masks for forming each layer therein, as well known in the art. The present method includes a first series of photolithography steps for manufacturing the first display panel 102 and a second series of photolithography steps for manufacturing the second display panel 104.

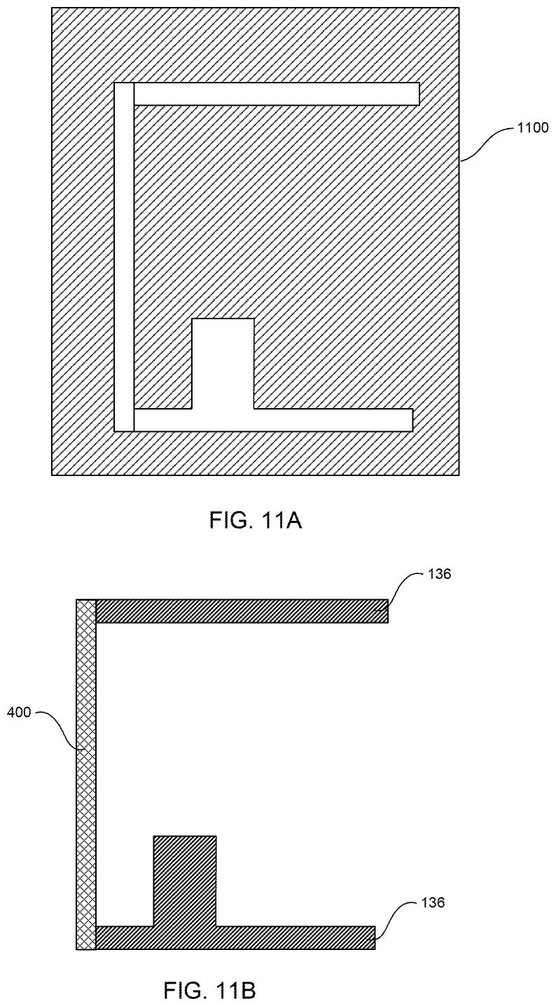

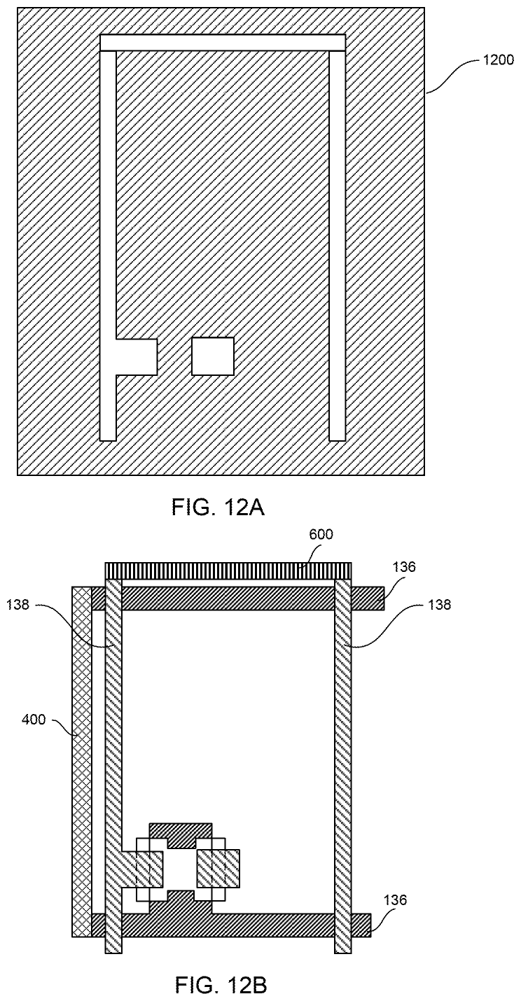

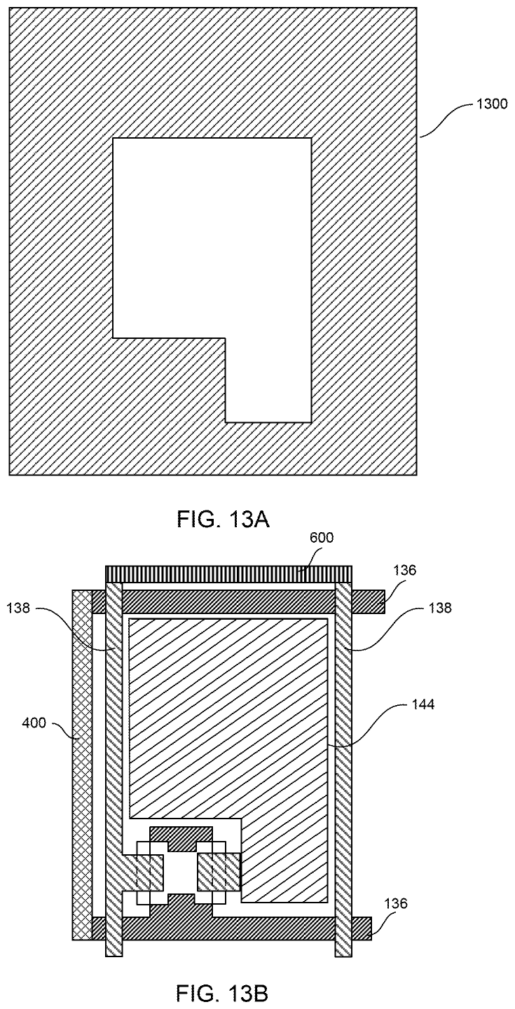

In an exemplary embodiment, the first series of photolithography steps includes a first gate line step of forming the plurality of first gate lines 136 by a first photo-mask 1100 (as shown in FIG. 11A). FIG. 11B depicts portions of the first gate lines 136 from the plurality of first gate lines 136 as formed by the first gate line step. As may be seen, two or more adjacent first gate lines 136 (as formed) from the plurality of first gate lines 136 are electrically connected to each other by the gate lead connector 400. Subsequently, the first series of photolithography steps includes forming a layer of amorphous silicon (not shown). Further, the first series of photolithography steps includes a first data line step of forming the plurality of first data lines 138 by a second photo-mask 1200 (as shown in FIG. 12A). FIG. 12B depicts portions of the first data lines 138 from the plurality of first data lines 138 as formed by the first data line step, on top of the formed portions of the first gate lines 136. As may be seen, two or more adjacent first data lines 138 (as formed) from the plurality of first data lines 138 are electrically connected to each other by the data lead connector 600. Subsequently, the first series of photolithography steps includes forming an insulating layer (not shown). Further, the first series of photolithography steps includes forming a common electrode (not shown). Then, the first series of photolithography steps includes forming a common metal layer (not shown). Thereafter, the first series of photolithography steps includes forming another through-hole (not shown). Further, the first series of photolithography steps includes a first pixel electrode step of forming the plurality of first pixel electrodes 144 by a third photo-mask 1300 (as shown in FIG. 13A). FIG. 13B depicts a portion of one of the first pixel electrodes 144 as formed by the first pixel electrode step, on top of the formed portions of the first gate lines 136 and the first data lines 138.

It may be understood that the photo-masks 1100, 1200 and 1300 (as shown) are only portions of actual photo-masks to be employed for forming corresponding layers of the first display panel 102. For example, the photo-masks 1100, 1200 and 1300 (as shown for illustration purposes) may be implemented for forming one of the first pixels 140 therein. In one or more examples, the plurality of gate lines 136 and the plurality of data lines 138 may be formed of Aluminum (Al) or Copper (Cu); however, it may be contemplated that other metals with high melting point, such as Chromium (Cr), Molybdenum (Mo), Tungsten (W), Titanium (Ti), Tantalum (Ta) or an alloy of two or more kinds of these metals, or a lamination film of two or more kinds of these metals or alloys, may be used without any limitations.

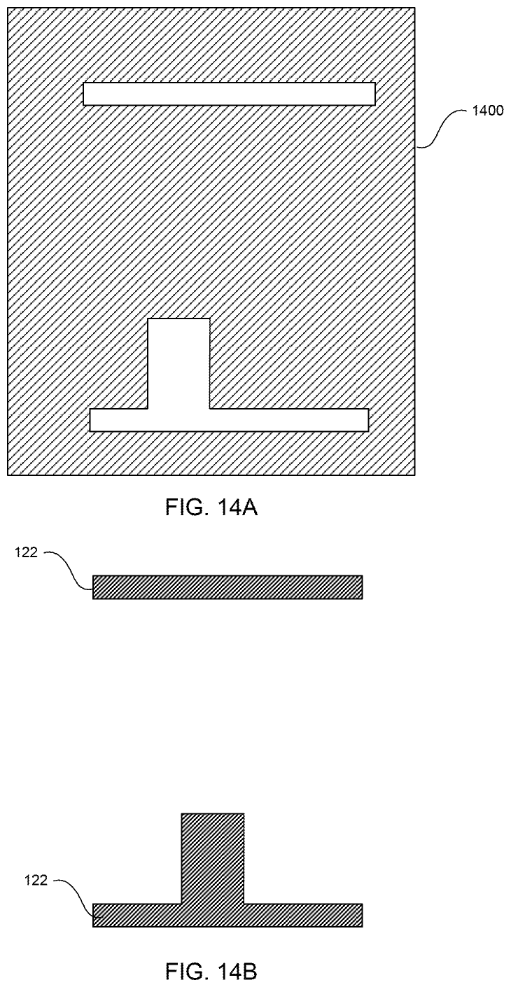

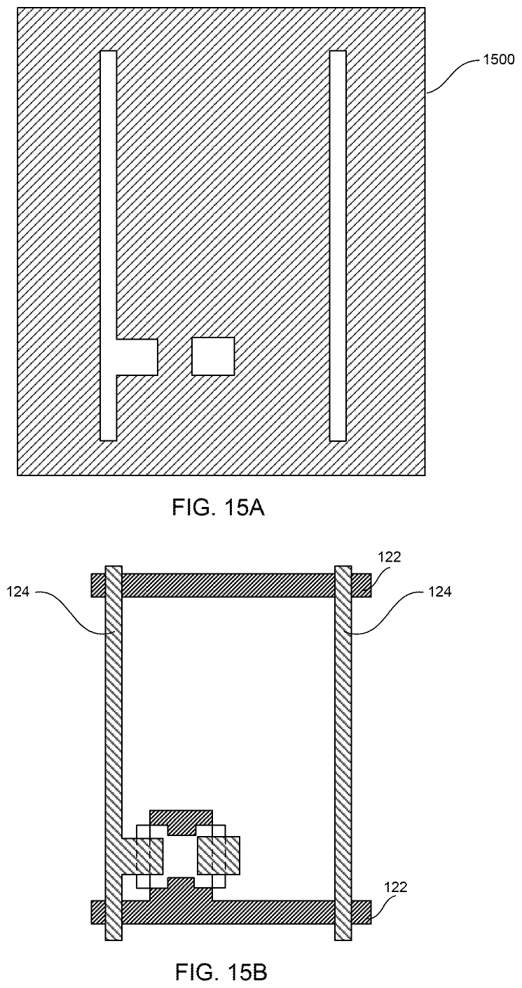

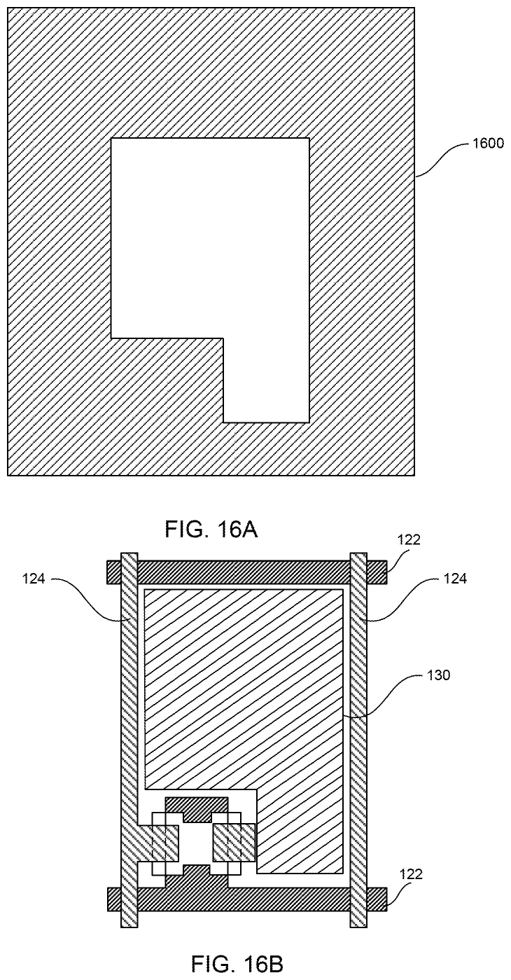

Further, in the present exemplary embodiment, the second series of photolithography steps includes a second gate line step of forming the plurality of second gate lines 136 by a fourth photo-mask 1400 (as shown in FIG. 14A). FIG. 14B depicts portions of the second gate lines 122 from the plurality of second gate lines 122 as formed by the second gate line step. Further, the second series of photolithography steps includes a second data line step of forming the plurality of second data lines 124 by a fifth photo-mask 1500 (as shown in FIG. 15A). FIG. 15B depicts portions of the second data lines 124 from the plurality of second data lines 124 as formed by the second data line step, on top of the formed portions of the second gate lines 122. Further, the second series of photolithography steps includes a second pixel electrode step of forming the plurality of second pixel electrodes 130 by a sixth photo-mask 1600 (as shown in FIG. 16A). FIG. 16B depicts a portion of one of the second pixel electrodes 130 as formed by the second pixel electrode step, on top of the formed portions of the second gate lines 122 and the second data lines 124.

It may be understood that the photo-masks 1400, 1500 and 1600 (as shown) are only portions of actual photo-masks to be employed for forming corresponding layers of the second display panel 102. For example, the photo-masks 1400, 1500 and 1600 (as shown for illustration purposes) may be implemented for forming one of the second pixels 126 therein. In one or more examples, the plurality of gate lines 122 and the plurality of data lines 124 may be formed of Aluminum (Al) or Copper (Cu); however, it may be contemplated that other metals with high melting point, such as Chromium (Cr), Molybdenum (Mo), Tungsten (W), Titanium (Ti), Tantalum (Ta) or an alloy of two or more kinds of these metals, or a lamination film of two or more kinds of these metals or alloys, may be used without any limitations.

It may be contemplated that in the present exemplary embodiment, the first series of photolithography steps may be implemented to form the first display panel 102 as shown in FIG. 8. In such exemplary embodiment, the third photo-mask 1300 and the sixth photo-mask 1600 have a same shape, as may also be seen from FIGS. 13A and 16A corresponding thereto. Further, at least one of the first photo-mask 1100 and the second photo-mask 1200 has a different shape from the fourth photo-mask 1400 and the fifth photo-mask 1500, respectively. In the illustrated exemplary embodiment, both of the first photo-mask 1100 and the second photo-mask 1200 may have a different shape from the fourth photo-mask 1400 and the fifth photo-mask 1500, respectively. However, still at least one of the photo-mask, such as the sixth photo-mask 1600 as employed for forming the second pixel electrodes 130 in the second pixel electrode step, may be common and be reused for forming the first pixel electrodes 144 in the first pixel electrode step.

In another exemplary embodiment, common shape of photo-mask is used in both each step from the first series of photolithography steps and each corresponding step from the second series of photolithography steps, other than at least one of both of the first gate line step and the second gate line step, and both of the first data line step and the second data line step. For instance, in one example, along with the third photo-mask 1300 and the sixth photo-mask 1600 being common, the first photo-mask 1100 and the fourth photo-mask 1400 may also be common, and thus the fourth photo-mask 1400 may be reused for forming the plurality of first gate lines 136 in the first gate line step (such as, as may be contemplated, for forming the first display panel of FIG. 6). In alternative example, along with the third photo-mask 1300 and the sixth photo-mask 1600 being common, the second photo-mask 1200 and the fifth photo-mask 1500 may also be common, and thus the fifth photo-mask 1500 may be reused for forming the plurality of first data lines 138 in the first data line step (such as, as may be contemplated, for forming the first display panel of FIG. 4).

Therefore, the method of manufacturing the liquid crystal display device 100 (as disclosed in the preceding paragraphs) reuses one or more photo-masks between the first series of photolithography steps for manufacturing the first display panel 102 and the second series of photolithography steps for manufacturing the second display panel 104. In one example, the first series of photolithography and the second series of photolithography may include more than seven steps, but can use the same photo masks, except one or two photo masks for gate line step and/or data line step. Thus, the present manufacturing method results in overall reduction in the required number of photo-masks, which, in turn, means reduction in manufacturing cost which could be significant in view of mass production of the liquid crystal display device 100.

The foregoing descriptions of specific embodiments of the present disclosure have been presented for purposes of illustration and description. They are not intended to be exhaustive or to limit the present disclosure to the precise forms disclosed, and obviously many modifications and variations are possible in light of the above teaching. The exemplary embodiment was chosen and described in order to best explain the principles of the present disclosure and its practical application, to thereby enable others skilled in the art to best utilize the present disclosure and various embodiments with various modifications as are suited to the particular use contemplated.

What is claimed is:

1. A liquid crystal display device comprising:
a first display panel comprising a plurality of first gate lines and a plurality of first data lines in a first display region thereof, and a second display panel comprising a plurality of second gate lines and a plurality of second data lines in a second display region thereof; and
a first driving circuit for one or more of the plurality of first gate lines and the plurality of first data lines, wherein the first driving circuit comprises one or more first drivers to provide signals to the one or more of the plurality of first gate lines and the plurality of first data lines,
wherein the first display panel and the second display panel overlap each other in plan view,
wherein the plurality of first gate lines and the plurality of first data lines correspond to the plurality of second gate lines and the plurality of second data lines, respectively, in the first display region and the second display region of the first display panel and the second display panel, and
wherein at least one of two or more adjacent first gate lines from the plurality of first gate lines and two or more adjacent first data lines from the plurality of first data lines are provided with same signals at a same instant of time.

2. The liquid crystal display device according to claim 1, wherein the first driving circuit comprises a first gate driving circuit for the plurality of first gate lines and the one or more first drivers comprise one or more first gate drivers to provide gate signals to the plurality of first gate lines, wherein two or more adjacent first gate lines from the plurality of first gate lines are provided with the same gate signals at the same instant of time.

3. The liquid crystal display device according to claim 2, wherein the two or more adjacent first gate lines from the plurality of first gate lines are electrically connected to each other by a gate lead connector, and wherein the gate lead connector is formed outside the first display region, and connects between the two or more adjacent first gate lines and one gate terminal of the one or more first gate drivers to receive the gate signals for the two or more adjacent first gate lines.

4. The liquid crystal display device according to claim 3, wherein the plurality of first gate lines include a first gate line group of the two or more adjacent first gate lines and a second gate line group of the two or more adjacent first gate lines, the first gate line group and the second gate line group being arranged adjacent to each other, and wherein a first gate terminal of the one or more first gate drivers electrically connects to the first gate line group, a second gate terminal of the one or more first gate drivers electrically connects to the second gate line group, and a third gate terminal of the one or more first gate drivers located between the first gate terminal and the second gate terminal is voided.

5. The liquid crystal display device according to claim 1, wherein the first driving circuit comprises a first data driving circuit for the plurality of first data lines and the one or more first drivers comprise one or more first data drivers to provide data signals to the plurality of first data lines, wherein two or more adjacent first data lines from the plurality of first data lines are provided with the same data signals at the same instant of time.

6. The liquid crystal display device according to claim 5, wherein the two or more adjacent first data lines from the plurality of first data lines are electrically connected to each other by a data lead connector, and wherein the data lead connector is formed outside the first display region, and connects between the two or more adjacent first data lines and one data terminal of the one or more first data drivers to receive the data signals for the two or more adjacent first data lines.

7. The liquid crystal display device according to claim 6, wherein the plurality of first data lines include a first data line group of the two or more adjacent first data lines and a second data line group of the two or more adjacent first data lines, the first data line group and the second data line group being arranged adjacent to each other, and wherein a first data terminal of the one or more first data drivers electrically connects to the first data line group, a second data terminal of the one or more first data drivers electrically connects to the second data line group, and a third data terminal of the one or more first data drivers located between the first data terminal and the second data terminal is voided.

8. The liquid crystal display device according to claim 1 further comprising a second driving circuit for one or more of the plurality of second gate lines and the plurality of second data lines, wherein the second driving circuit comprises one or more second drivers to provide signals to the one or more of the plurality of second gate lines and the plurality of second data lines, and wherein a number of first drivers are less than a number of second drivers.

9. The liquid crystal display device according to claim 1 further comprising a second driving circuit for one or more of the plurality of second gate lines and the plurality of second data lines, wherein the second driving circuit comprises one or more second drivers to provide signals to the one or more of the plurality of second gate lines and the plurality of second data lines, and wherein a number of terminals in the one or more first drivers are less than a number of terminals in the one or more second drivers.

10. A liquid crystal display device comprising:
a first display panel comprising a plurality of first gate lines and a plurality of first data lines in a first display region thereof, wherein two adjacent first gate lines from the plurality of first gate lines and two adjacent first data lines from the plurality of first data lines define a first pixel in the first display region;
a second display panel comprising a plurality of second gate lines and a plurality of second data lines in a second display region thereof, wherein two adjacent second gate lines from the plurality of second gate lines and two adjacent second data lines from the plurality of second data lines define a second pixel in the second display region,
wherein the first display panel and the second display panel overlap each other in plan view,
wherein the first display panel and the second display panel have equal densities of first pixels and second pixels, respectively, therein, and
wherein the first display panel displays at a lower definition as compared to the second display panel.

11. The liquid crystal display device according to claim 10, wherein the first display panel comprises a first gate driving circuit comprising one or more first gate drivers to provide gate signals to the plurality of first gate lines, wherein two or more adjacent first gate lines from the plurality of first gate lines are provided with gate signals at a same instant of time.

12. The liquid crystal display device according to claim 11, wherein the two or more adjacent first gate lines from the plurality of first gate lines are electrically connected to each other by a gate lead connector, and wherein the gate lead connector is formed outside the first display region, and connects between the two or more adjacent first gate lines and one gate terminal of the one or more first gate drivers to receive the gate signals for the two or more adjacent first gate lines.

13. The liquid crystal display device according to claim 12, wherein the plurality of first gate lines include a first gate line group of the two or more adjacent first gate lines and a second gate line group of the two or more adjacent first gate lines, the first gate line group and the second gate line group being arranged adjacent to each other, and wherein a first gate terminal of the one or more first gate drivers electrically connects to the first gate line group and a second gate terminal of the one or more first gate drivers electrically connects to the second gate line group and a third gate terminal of the one or more first gate drivers located between the first gate terminal and the second gate terminal is voided.

14. The liquid crystal display device according to claim 10, wherein the first display panel comprises a first data driving circuit comprising one or more first data drivers to provide data signals to the plurality of first data lines, wherein two or more adjacent first data lines from the plurality of first data lines are provided with data signals of same gray scale at the same instant of time.

15. The liquid crystal display device according to claim 14, wherein the two or more adjacent first data lines from the plurality of first data lines are electrically connected to each other by a data lead connector, and wherein the data lead connector is formed outside the first display region, and connects between the two or more adjacent first data lines and one data terminal of the one or more first data drivers to receive the data signals for the two or more adjacent first data lines.

16. The liquid crystal display device according to claim 15, wherein the plurality of first data lines include a first data line group of the two or more adjacent first data lines and a second data line group of the two or more adjacent first data lines, the first data line group and the second data line group being arranged adjacent to each other, and wherein a first data terminal of the one or more first data drivers electrically connects to the first data line group and a second data terminal of the one or more first data drivers electrically connects to the second data line group and a third data terminal of the one or more first data drivers located between the first data terminal and the second data terminal is voided.

17. A method of manufacturing a liquid crystal display device,
the liquid crystal display device comprising:
a first display panel including a plurality of first gate lines, a plurality of first data lines, and a plurality of pixel electrodes in a first display region thereof, and
a second display panel comprising a plurality of second gate lines and a plurality of second data lines, and a plurality of second pixel electrodes in a second display region thereof, the first display panel and the second display panel overlapping each other in plan view,
the method comprising:
a first series of photolithography steps for manufacturing the first display panel; and
a second series of photolithography steps for manufacturing the second display panel, wherein:
the first series of photolithography steps comprises:
a first gate line step of forming the plurality of first gate lines by a first photo-mask,
a first data line step of forming the plurality of first data lines by a second photo-mask, and
a first pixel electrode step of forming the plurality of first pixel electrodes by a third photo-mask;
the second series of photolithography steps comprises:
a second gate line step of forming the plurality of second gate lines by a fourth photo-mask,
a second data line step of forming the plurality of second data lines by a fifth photo-mask, and
a second pixel electrode step of forming the plurality of second pixel electrodes by a sixth photo-mask,
wherein the third photo-mask and the sixth photo-mask have a same shape, and at least one of the first photo-mask and the second photo-mask has a different shape from the fourth photo-mask and the fifth photo-mask, respectively.

18. The method according to claim 17, wherein common shape of photo-mask is used in both each step from the first series of photolithography steps and each corresponding step from the second series of photolithography steps, other than at least one of both of the first gate line step and the second gate line step, and both of the first data line step and the second data line step.

19. The method according to claim 17, wherein the first photo-mask has a different shape from the fourth photo-mask, and the second photo-mask has a different shape from the fifth photo-mask.

20. The method according to claim 17, wherein two or more adjacent first gate lines from the plurality of first gate lines are electrically connected to each other by a gate lead connector, two or more adjacent first data lines from the plurality of first data lines are electrically connected to each other by a data lead connector, or the two or more adjacent first gate lines and the two or more adjacent first data lines are electrically connected to each other by the gate lead connector and the data lead connector, respectively.
